(19) United States
(12) Patent Application Publication
(10) Pub. No.: US 2007/0173017 A1
(43) Pub. Date: Jul. 26, 2007

(54) Advanced non-volatile memory array and method of fabrication thereof

(75) Inventors: Boaz Eitan, Ra'anana (IL); Eli Lusky, Tel-Aviv (IL)

Correspondence Address: EMPK & SHILOH, LLP, 116 John St., Suite 1201, New York, NY, 10038, US

(73) Assignee: Saifun Semiconductors, Ltd., Netanya (IL)

(21) Appl. No.: 11/336,093

(22) Filed: Jan. 20, 2006

(51) Int. Cl. H01L 21/336

(52) U.S. Cl. 438/257

(57) ABSTRACT

A method for creating a non-volatile memory array includes generating removable mask columns to define bit lines, implanting bit lines into the substrate at least between the columns, depositing oxide filler over the bit lines, removing the mask columns, depositing a polysilicon layer over the array and etching the polysilicon layer into word lines. The polysilicon extends at least into spaces left behind by the removed mask columns. The method also includes performing a dual work integration doping after the word line patterning.

### FIELD OF THE INVENTION

The present invention relates to non-volatile memory arrays generally and to a method of fabrication thereof in particular.

### BACKGROUND OF THE INVENTION

Dual bit memory cells are known in the art. One such memory cell is the NROM (nitride read only memory) cell 10, shown in FIG. 1A to which reference is now made, which stores two bits 12 and 14 in a nitride based layer 16, such as an oxide-nitride-oxide (ONO) stack, sandwiched between a polysilicon word line 18 and a channel 20. Channel 20 is defined by buried bit line diffusions 22 on each side which are isolated from word line 18 by a thermally grown oxide layer 26, grown after bit lines 22 are implanted. During oxide growth, bit lines 22 may diffuse sideways, expanding from the implantation area.

NROM cells are described in many patents, for example in U.S. Pat. No. 6,649,972, assigned to the common assignees of the present invention, whose disclosure is incorporated herein. As shown in FIG. 1B, to which reference is now briefly made, NROM technology employs a virtual-ground array architecture with a dense crisscrossing of word lines 18 and bit lines 22. Word lines 18 and bit lines 22 optimally can allow a 4F² size cell, where F designates the design rule (i.e. minimum size of an element) of the technology in which the array was constructed. For example, the design rule for a 0.5 μm technology is F=0.5 μm. However, most NROM technologies which use the more advanced processes of less than 0.1 μm employ a larger cell, of 5-6F² due to the side diffusion of the bit lines.

A common problem is the integrity of bit line oxides 26. As can be seen in FIG. 1A, they are thick in a middle 25 but shrink to an “oxide beak” 27 at the sides. In general, middles 25 are of good quality but beaks 27 are of poor quality, and thus are susceptible to breakdown. Moreover, the thickness of middles 25 is sensitive to the concentration of n+doping at the surface of bit line 22 and is thus, difficult to control. In older generation technologies, the solution to this was high temperature oxidation. However, this causes substantial thermal drive, which increases the side diffusion of bit lines 22.The following patents and patent applications attempt to solve these issues and to improve scaling. US 2004/0157393 to Hwang describes a manufacturing process for a non-volatile memory cell of the SONOS type which attempts to reduce or minimize the undesirable effects of small dimension components. U.S. Pat. No. 6,686,242 B2 to Wilier et al. describes an NROM cell that they claim can be implemented within a 4F² area. U.S. Ser. No. 11/247,733, filed Oct. 11, 2005 and assigned to the common assignees of the present invention, describes a further process for manufacturing NROM cells.

Each of the above patents and patent applications utilizes a dual poly process (DPP), where a first polysilicon layer is deposited in columns between which bit lines 22 are implanted. Word lines 18 are then deposited as a second polysilicon layer, cutting the columns of the first polysilicon layer into islands between bit lines 22.

Unfortunately, the DPP process has its drawbacks. It makes it difficult, if not impossible, to achieve “dual work function integration”. The first polysilicon layer can be doped with n+ and will make both the memory transistors and the n-channel periphery transistors perfect enhancement devices. Unfortunately the p-channel transistors will also have an n+ doped polysilicon layer; hence they will become depletion type devices. These depletion devices are not adequate for low voltage CMOS. Counter doping the n+ first polysilicon layer is impractical due to the high concentration of the n+ in the polysilicon, the double layers of polysilicon, which are extra thick, and the minimum thermal budget available when implanting the p+ source and drains (and the polysilicon gates of the p-channel transistors). Other solutions, like the removal of the first polysilicon layer from the periphery, only highly complicate the entire process and hence, are not considered practical.

### SUMMARY OF THE PRESENT INVENTION

The present invention may provide a novel non-volatile memory device as well as a novel method of manufacture.

There is therefore provided, in accordance with a preferred embodiment of the present invention, a method for creating a non-volatile memory array. The method includes generating removable mask columns to define bit lines, implanting bit lines into the substrate at least between the columns, depositing oxide filler over the bit lines, removing the removable mask columns, depositing a polysilicon layer over the array, the polysilicon extending at least into spaces left behind by the removed mask columns and etching the polysilicon layer into word lines.

Additionally, in accordance with a preferred embodiment of the present invention, the depositing includes depositing a nitride hard mask covering the polysilicon layer and etching the nitride hard mask and polysilicon layer generally simultaneously into word lines.

Moreover, in accordance with a preferred embodiment of the present invention, the removable mask is a nitride hard mask.

Additionally, in accordance with a preferred embodiment of the present invention, the method can also include implanting a pocket implant at least next to the removable mask columns. In one embodiment, the implant has a tilt of 0-15 degrees. The pocket implant can be of Boron, BF2 or Indiwn.

Further, in accordance with a preferred embodiment of the present invention, the non-volatile memory array is a nitride read only memory (NROM) array.

Still further, in accordance with a preferred embodiment of the present invention, the method can also include implanting an anti-punchthrough implant after the last step of etching into the areas between the bit lines not covered by the word lines. Prior to the step of implanting the anti-punchthrough implant, the method can include forming a liner or a spacer to cover word lines. If desired, the anti-punchthrough implant may be a combination of implants.

Additionally, in accordance with a preferred embodiment of the present invention, the method can also include reducing the width between the removable mask columns before implanting the bit lines. In one embodiment, the reducing includes depositing oxide to reduce the width. The oxide can be a liner or a spacer.

Moreover, in accordance with a preferred embodiment of the present invention, the method also includes performing a dual work function doping after etching the word lines. The doping can be implanted into the memory array.

Further, in accordance with a preferred embodiment of the present invention, the method can also include performing salicidation after the doping.

There is also provided, in accordance with a preferred embodiment of the present invention, a method for creating a non-volatile memory array where the method includes generating columns of short charge trapping dielectric, generating blocked columns of bit line oxides between the dielectric columns and self-aligned above diffusion bit lines and generating word lines of polysilicon layer thin enough to enable dual work function integration in non-memory transistors. The word lines can be formed of rows perpendicular to and on top of the bit line oxide columns and with gates extending between neighboring the columns from the rows to the dielectric columns.

Additionally, in accordance with a preferred embodiment of the present invention, the generating columns together includes generating removable mask columns on top of an oxide-nitride-oxide (ONO) layer, implanting bit lines into the substrate at least between the columns, depositing oxide filler over the bit lines and removing the removable mask columns.

Moreover, in accordance with a preferred embodiment of the present invention, the removable mask is a nitride hard mask.

Further, in accordance with a preferred embodiment of the present invention, the generating word lines includes depositing a polysilicon layer over the array, the polysilicon extending at least into spaces left behind by the removed mask columns and etching the polysilicon layer into word lines.

Still further, in accordance with a preferred embodiment of the present invention, the method can also include implanting a pocket implant at least next to the removable mask columns.

There is also provided, in accordance with a preferred embodiment of the present invention, a non-volatile memory array including columns of diffusion bit lines implanted in the semiconductor substrate, blocked columns of bit line oxides self-aligned above a reduced width of the diffusion bit lines, columns of charge trapping dielectric between the blocked columns, the dielectric columns being shorter in height than the blocked columns, and word lines of a polysilicon layer thin enough to enable dual work function integration in non-memory transistors, the word lines formed of rows perpendicular to and on top of the blocked columns and with gates extending between neighboring the columns from the rows to the ONO columns.

Moreover, in accordance with a preferred embodiment of the present invention, the array can also include an anti-punchthrough implant in the areas between the bit lines not covered by the word lines.

Further, in accordance with a preferred embodiment of the present invention, the array can also include pocket implants at least next to the diffusion bit lines.

Still further, in accordance with a preferred embodiment of the present invention, the word lines include dual work function doping.

Still further, in accordance with a preferred embodiment of the present invention, the non-volatile memory array is a nitride read only memory (NROM) array.

Finally, there is provided, in accordance with a preferred embodiment of the present invention, a method for creating a non-volatile memory array,.the method including generating at least nitride hard mask columns to define bit lines, implanting bit lines into the substrate at least between the columns, depositing oxide filler over the bit lines, removing the nitride hard mask columns, depositing a polysilicon layer over the array, the polysilicon extending at least into spaces left behind by the removed nitride hard mask columns, depositing a nitride hard mask layer covering the polysilicon and etching the nitride hard mask and polysilicon layer into word lines.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1A is a schematic illustration of an NROM memory cell;

FIG. 1B is a schematic illustration of a layout of the cell of FIG. 1A;

FIGS. 2A and 2B together are a flow chart illustration of a manufacturing method for a novel memory cell;

FIGS. 3A, 3B, 3C, 3D, 3E, 3F, 3G, 3H and 3I are schematic illustrations of the memory cell in various stages of the method of FIGS. 2A and 2B; and

FIGS. 4A and 4B are layout illustrations useful in understanding the method of FIGS. 2A and 2B.

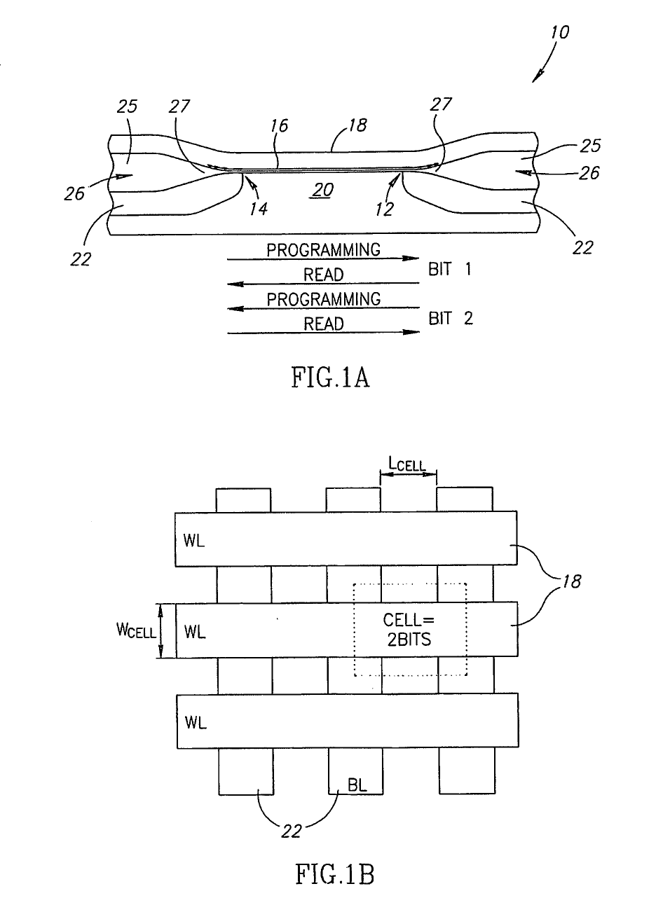

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

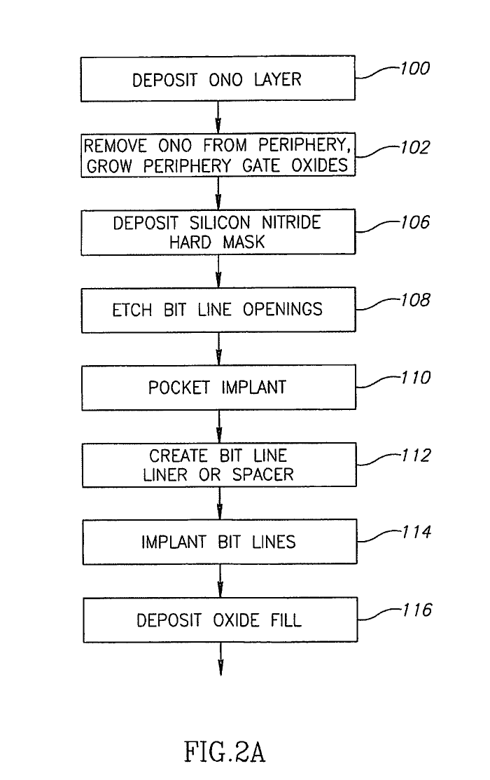

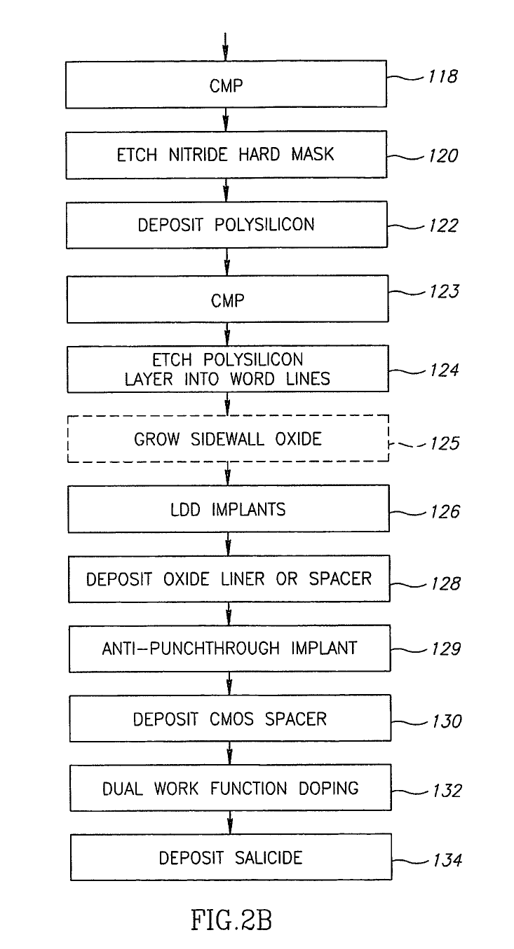

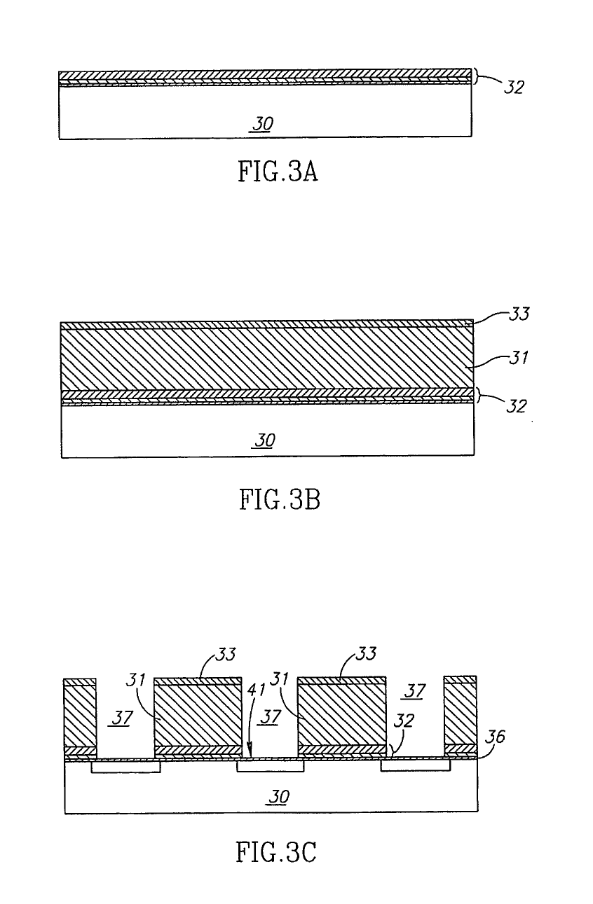

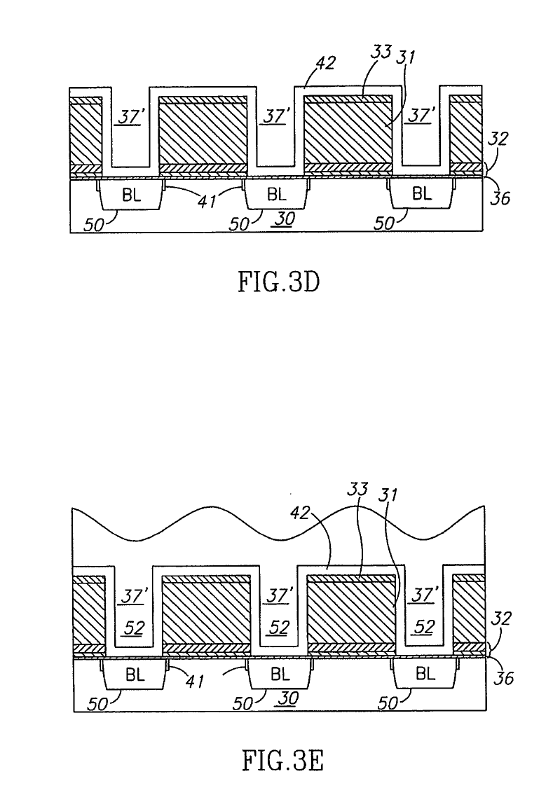

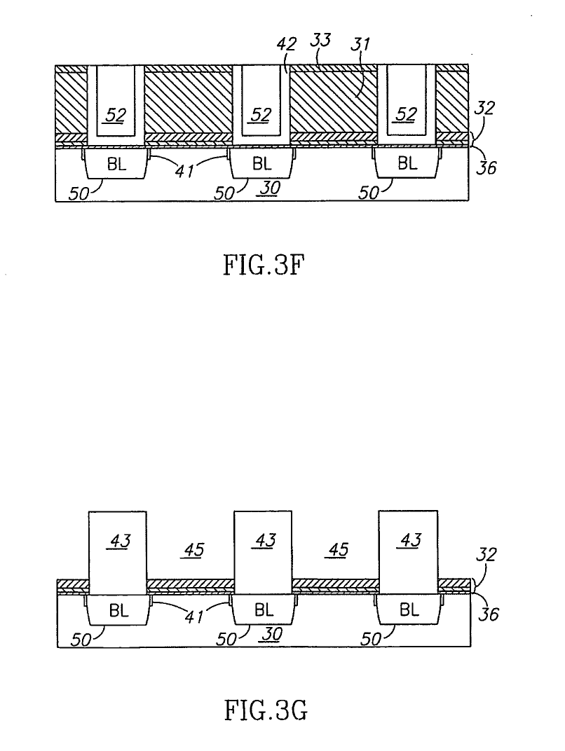

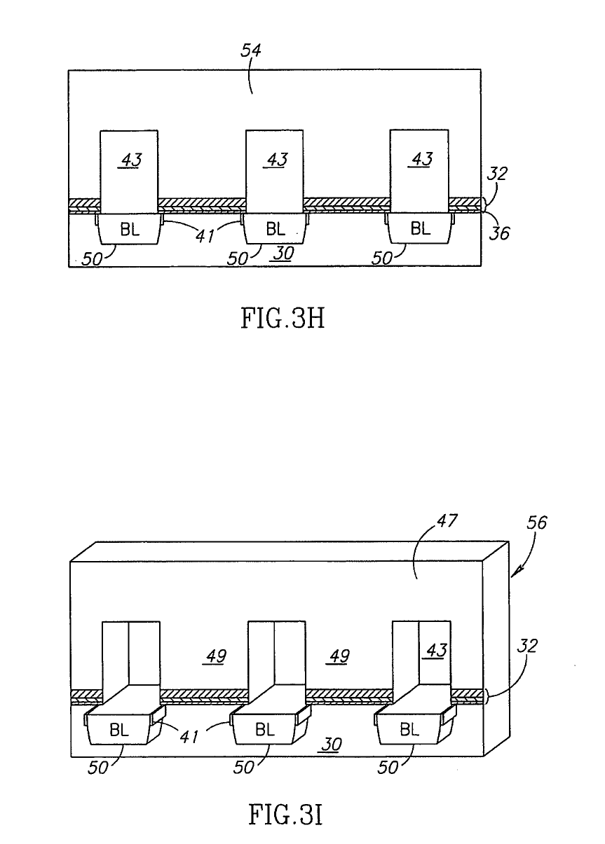

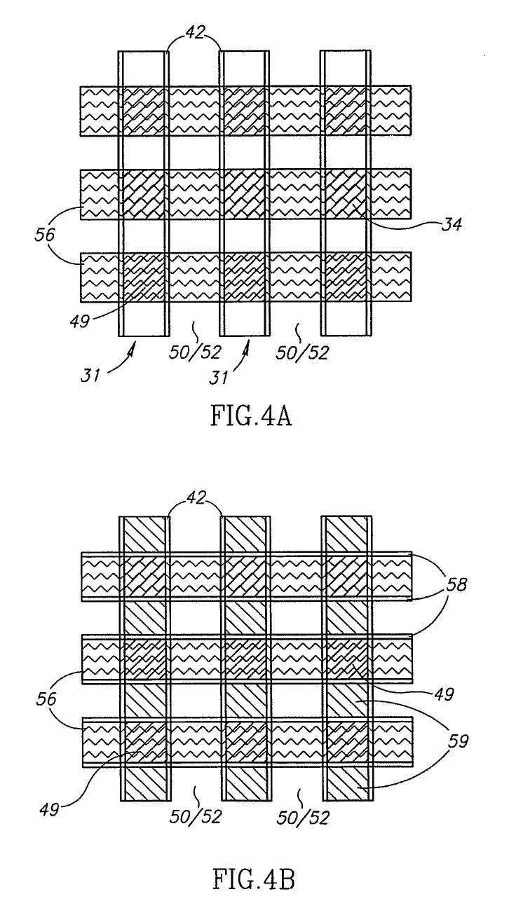

Reference is now made to FIGS. 2A and 2B, which, together, illustrate a novel process for manufacturing nitride read only memory (NROM) arrays which may eliminate the first polysilicon layer in the dual poly process (DPP). Reference is also made to FIGS. 3A-3I which show the results of various steps of FIGS. 2A and 2B and to FIGS. 4A and 4B which show the layout of various steps of FIGS. 2A and 2B.

After preparation of a substrate 30 (FIG. 3A), an ONO layer 32 may be laid down (step 100) over the entire wafer, where, in an exemplary embodiment, the bottom oxide layer may be 3-7 nm thick, the nitride layer may be 3-7 nm thick and the gate oxide layer may be 6-14 nm thick.

A mask may be laid down and ONO layer 32 may be removed (step 102) from the periphery (e.g. area of the chip designated for CMOS operation), after which the gate oxides of the periphery may be grown and a threshold voltage doping may be implanted for the CMOS periphery. It will be appreciated that the operations of step 102 are high thermal budget operations. Moreover, as will be seen hereinbelow, they are the last high thermal budget operations in the present process.

In step 106, a silicon nitride hard mask 31 may be laid down over the entire chip. If desired, mask 31 may be covered by a SiON coating 33. An exemplary mask 31 may be 30-100 nm thick and the optional SiON coating 33 may be 10-30 nm thick.

An etch may be performed (step 108) to generate bit line openings 37 (FIG. 3C). The etch may involve laying down a photoresist and exposing it to an ultraviolet (UV) light in a column pattern covering the areas of the memory array not destined to be bit lines and also covering the periphery. A nitride etch may be performed, which may be set to stop at the bottom oxide, labeled 36. It may leave bottom oxide 36 or may etch a portion of it, ideally leaving 2 nm. Alternatively, the etch may be stopped on the top oxide or in the nitride.

FIG. 3C shows the results of step 106. A few columns of nitride hard mask 31 with optional coating 33 are shown on top of ONO layer 32, now also in columns, and bottom oxide 36 is shown on top of substrate 30 in bit line openings 37.

A pocket implant 41, such as of BF₂, may now be implanted (step 110) next to or under nitride columns 31. An exemplary pocket implant may be of 0.5-5×10¹³/cm² at an angle of 0-15°, where the angle may be limited by the width of bit line opening 37 and the height of nitride hard mask 31 and optional coating 33. Part of pocket implant 41 may scatter and diffuse under nitride columns 31. In an alternative embodiment, the pocket implant may be of Boron or Indium.

In step 112, a bit line liner 42, such as of 12-25 nm thick oxide, may be generated around nitride columns 31. Alternatively, bit line spacers may be generated by etching, with an anisotropic etch, of liner 42. Bit line liner or spacer 42 may decrease the width of bit line openings, labeled 37′ in FIG. 3D, in order to reduce the width of the about-to-be implanted bit lines and to increase the effective length of the channels between bit lines.

Once bit line liner 42 has been deposited, bit lines 50 may be implanted (step 114), followed by a spike rapid thermal anneal (RTA). As shown in FIG. 3D, during the rapid thermal anneal, bit lines 50 may diffuse deeper into substrate 30 and sideways, under the columns of ONO layer 32 and nitride hard mask 31. In one exemplary embodiment, the bit line implant is of Arsenic of 1-2×10¹⁵/cm² at 10-20 Kev and with an angle of 0 or 7% to substrate 30 in the direction of bit lines 50.

In step 116, an oxide filler 52 may be deposited on the wafer. As can be seen in FIG. 3E, oxide filler 52 may fill reduced bit line openings 37′ and may also cover other parts of the wafer. In step 118, a CMP (chemical mechanical planarization) process may be performed to remove excess oxide filler 52 and, if present, excess bit line liner 42, typically back to SiON coating 33. The result of step 118 is shown in FIG. 3F.

In step 120, optional SiON coating 33 and nitride hard mask 31 may be removed from the wafer, typically via a nitride wet etch. As shown in FIG. 3G, this step may leave ONO columns 32 exposed between bit line oxides 43, formed of oxide filler 52, bit line oxide liner 42 and bottom oxide 36. It will be appreciated that bit line oxides 43, which are also exposed, are formed as blocked columns with openings 45 therebetween. Openings 45 may be self-aligned above ONO columns 32 and may define the channel length of the cell transistor.

In step 122, a polysilicon layer 54 may be deposited on the entire wafer and in step 123, it may be planarized (typically via a CMP step). As shown in FIG. 3H, polysilicon layer 54 may cover bit line oxides 43 and may fill openings 45, thereby covering ONO columns 32,

Polysilicon layer 54 may then be etched (step 124) into word lines 56 (FIG. 31), which may be in rows perpendicular to the bit line columns. To etch the word lines, a photo resist mask or a nitride hard mask may be laid down over polysilicon layer 54, followed by exposure and etch of the mask and polysilicon layer 54 into word lines 56. The etch may occur in two steps or as a single step and may continue into one or more of the ONO layers 32 or not, as desired. The WL definition mask may also define the CMOS transistor gates.

FIG. 31 is an isometric illustration of one word line 56 and three bit lines 50 perpendicular thereto. Word line 56 may be formed of a row 47, perpendicular to bit lines 50 and connecting a plurality of gates 49 isolated by bit line oxides 43 (not shown for clarity). Each gate 49 may extend down from row 47 and may control the portion of ONO layer 32 thereunder. As mentioned hereinabove, ONO layer 32 may be etched into islands under gates 49 or may remain as columns between bit line oxides 43.

It will be appreciated that gates 49 may be formed of the same polysilicon layer as rows 47 and thus, word lines 56 may be formed of a single polysilicon layer. As will be discussed hereinbelow, this may enhance the array's ability to receive dual work function doping. Moreover, since the present process has only one polysilicon deposition step, the periphery transistors also only have one layer of polysilicon on them. This may enhance their ability to receive dual work function doping.

It will further be appreciated that bit lines 50 may be self-aligned at least next to and typically, slightly under, polysilicon gates 49 and that bit line oxides 43 may be self-aligned to polysilicon gates 49. Furthermore, word lines 56 may extend above and perpendicular to buried diffusion bit lines 50, which may be insulated from them by blocked bit line oxides 43.

The layout of the array may be seen more clearly in FIG. 4A. As can be seen, nitride hard mask 31 and ONO elements 32 may be laid out in columns, with liners or spacers 42 to their sides. Bit lines 50 may be implanted between spacers 42 and covered by oxide filler 52. Once nitride hard mask 31 is removed, word lines 56 may be laid out in rows, with gates 49 extending into the columns between bit lines 50. As can be seen, when word lines 56 are etched, the polysilicon between rows 56 may be etched, leaving polysilicon gates 49.

As mentioned hereinabove, polysilicon layer 54 may additionally form the gates, and possibly some interconnections, in the CMOS periphery.

A sidewall oxide 58 (FIG. 4B) may optionally be generated (step 125) to cover the word line surfaces that may be exposed as a result of etch step 124.

In step 126, the lightly doped drain (LDD) implants for the CMOS transistors may be implanted. There is typically one mask for the n-LDD implants (for n-channel devices) and another mask for the p-LDD implants (for p-channel devices) Both implants may be of 1-5×10³/cm².

An oxide liner or partial spacer, of about 10-20 nm, may then be deposited (step 128), along and between word lines 56. This liner may serve as part of the CMOS spacer and may be completed after implanting of an anti-punchthrough implant 59 (step 129). However, if salicidation of word lines 56 is desired (as shown in step 134), an oxide spacer may be preferred in order to remove the oxide covering word lines 56 and to enable word lines 56 to be salicidized.

In step 129, anti-punchthrough implant 59 may be implanted through the oxide liner, in the spaces between bit lines 50 not covered by word lines 56. An exemplary anti-punchthrough implant may be of Boron (B) of 15 Kev at 5×10²/cm² or 30 Kev at 3×10¹²/cm². Alternatively, the anti-punchthrough implant may comprise a multiplicity of implants with different energies and doses in the same location. For example, there might be three consecutive implants of Boron, of 5×10¹² at 15 Kev, 3×10¹² at 25 Kev and 3×10¹² at 35 Kev. Alternatively, the Boron may be replaced by BF₂ or Indium.

With the anti-punchthrough implant, processing of the memory array is mostly finished and processing of the CMOS periphery and any CMOS transistors in the array may be continued.

In step 130, oxide spacers may be deposited for the CMOS transistors. The deposition may cover the entire wafer and may fill or partially fill between word lines 56, providing insulation between word lines 56.

In step 132, dual work function doping may occur. Once again, there may be two masks, one to define the n+ doping of the gates of the n-channel transistors and another to define the p+ doping of the gates of the p-channel transistors. Step 132 may provide the correct work function for the CMOS transistors, such that both n-channel and p-channel transistors are enhancement devices. If desired, the dual work function doping may also be provided to the memory cells, which are typically n-channel devices. Alternatively, they may be p-channel devices and thus, can receive the p+ doping.

It will be appreciated that, since word lines 56 may be formed of a relatively thin polysilicon layer, the doping may diffuse therethrough to polysilicon gates 49.

In step 134, a salicide process (i.e. self-aligned silicidation), such as is known in the art, may be performed on the chip. This process may cause salicidation of the polysilicon throughout the chip which may reduce the resistances of the word lines and of the CMOS junctions.

In an alternative embodiment, the salicide deposition may be replaced with a standard silicide deposition. In this embodiment, the silicide deposition may occur after deposition of polysilicon layer 54, in which case, step 134 may be omitted. The remaining steps do not change. It is noted that silicide may reduce the resistance of polysilicon layer 54 but not of the CMOS junctions.

It will be appreciated that the present invention may be applicable to other types of memory arrays which are manufactured with a DPP or DPP-like process. The present invention, thus, is not restricted to NROM or NROM-like devices. For example, SONOS memory devices can benefit from this concept.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A method for creating a non-volatile memory array, the method comprising:
generating removable mask columns to define bit lines;
implanting bit lines into said substrate at least between said columns;
depositing oxide filler over said bit lines;
removing said removable mask columns;
depositing a polysilicon layer over said array, said polysilicon extending at least into spaces left behind by said removed mask columns; and
etching said polysilicon layer into word lines.

2. The method according to claim 1 and wherein said depositing comprises depositing a nitride hard mask covering said polysilicon layer and etching said nitride hard mask and polysilicon layer generally simultaneously into word lines.

3. The method according to claim 1 and wherein said removable mask is a nitride hard mask.

4. The method according to claim 1 and also comprising implanting a pocket implant at least next to said removable mask columns.

5. The method according to claim 4 and wherein said implant has a tilt of 0-15 degrees.

6. The method according to claim 4 and wherein said pocket implant is of one of the following materials: Boron, BF2 and Indium.

7. The method according to claim 1 and wherein said non-volatile memory array is a nitride read only memory (NROM) array.

8. The method according to claim 1 and also comprising implanting an anti-punchthrough implant after said last step of etching into the areas between said bit lines not covered by said word lines.

9. The method according to claim 8 and comprising prior to said step of implanting said anti-punchthrough implant, forming one of the following: a liner and a spacer to cover word lines.

10. The method according to claim 7 and wherein the anti-punchthrough implant is a combination of implants.

11. The method according to claim 1 and also comprising reducing the width between said removable mask columns before implanting said bit lines.

12. The method according to claim 11 and wherein said reducing comprises depositing oxide to reduce said width.

13. The method according to claim 12 and wherein said oxide is one of the following: a liner and a spacer.

14. The method according to claim 1 and also comprising performing a dual work function doping after etching said word lines.

15. The method according to claim 14 and also comprising implanting said dual work function doping into said memory array.

16. The method according to claim 14 and also comprising performing salicidation after said doping.

17. A method for creating a non-volatile memory array, the method comprising:
generating columns of short charge trapping dielectric;
generating blocked columns of bit line oxides between said dielectric columns and self-aligned above diffusion bit lines; and
generating word lines of polysilicon layer thin enough to enable dual work function integration in non-memory transistors, said word lines formed of rows perpendicular to and on top of said bit line oxide columns and with gates extending between neighboring said columns from said rows to said dielectric columns.

18. The method according to claim 17 and wherein said generating columns together comprise:
generating removable mask columns on top of an oxide-nitride-oxide (ONO) layer;
implanting bit lines into said substrate at least between said columns;
depositing oxide filler over said bit lines; and
removing said removable mask columns.

19. The method according to claim 18 and wherein said removable mask is a nitride hard mask.

20. The method according to claim 18 and wherein said generating word lines comprises:
depositing a polysilicon layer over said array, said polysilicon extending at least into spaces left behind by said removed mask columns; and
etching said polysilicon layer into word lines.

21. The method according to claim 18 and also comprising implanting a pocket implant at least next to said removable mask columns.

22. The method according to claim 17 and wherein said non-volatile memory array is a nitride read only memory (NROM) array.

23. The method according to claim 17 and also comprising implanting an anti-punchthrough implant after said generating word lines into the areas between said bit lines not covered by said word lines.

24. The method according to claim 18 and also comprising reducing the width between said removable mask columns before implanting said bit lines.

25. The method according to claim 17 and also comprising performing a dual work function doping after generating said word lines.

26. The method according to claim 25 and also comprising performing salicidation after said doping.

27. A non-volatile memory array comprising:
columns of diffusion bit lines implanted in said semiconductor substrate;
blocked columns of bit line oxides self-aligned above a reduced width of said diffusion bit lines;
columns of charge trapping dielectric between said blocked columns, said dielectric columns being shorter in height than said blocked columns; and
word lines of a polysilicon layer thin enough to enable dual work function integration in non-memory transistors, said word lines formed of rows perpendicular to and on top of said blocked columns and with gates extending between neighboring said columns from said rows to said ONO columns.

28. The array according to claim 27 and also comprising an anti-punchthrough implant in the areas between said bit lines not covered by said word lines.

29. The array according to claim 27 and also comprising pocket implants at least next to said diffusion bit lines.

30. The array according to claim 27 and wherein said word lines include dual work function doping.

31. The array according to claim 30 and wherein said word lines are salicidized word lines.

32. The array according to claim 27 and wherein said non-volatile memory array is a nitride read only memory (NROM) array.

33. A method for creating a non-volatile memory array, the method comprising:
generating at least nitride hard mask columns to define bit lines;
implanting bit lines into said substrate at least between said columns;
depositing oxide filler over said bit lines;
removing said nitride hard mask columns;
depositing a polysilicon layer over said array, said polysilicon extending at least into spaces left behind by said removed nitride hard mask columns;
depositing a nitride hard mask layer covering the polysilicon; and
etching said nitride hard mask and polysilicon layer into word lines.
